(19) United States
(12) Patent Application Publication
(10) Pub. No.: US 2008/0296000 A1
(43) Pub. Date: Dec. 4, 2008

(54) COOLING DEVICE FOR COMPUTER

(75) Inventor: Geoff Sean Lyon, Calgary (CA)

Correspondence Address: ADVANCED MICRO DEVICES, INC.;C/O VEDDER PRICE P.C., 222 N.LASALLE STREET, CHICAGO, IL, 60601, US

(73) Assignee: Advanced Micro Devices, Inc., Synnyvale, CA (US)

(21) Appl. No.: 12/129,993

(22) Filed: May 30, 2008

Related U.S. Application Data
(60) Provisional application No. 60/941,597, filed on Jun. 1, 2007.

(51) Int. Cl. F28D 15/00; H05K 7/20

(52) U.S. Cl. 165/104.33; 361/695; 165/104.34; 165/104.31

(57) ABSTRACT

A cooling device (1003) with a housing (1004) having an upper wall (1414b), lower wall (1414d), and two sidewalls, forming a duct with a cross-sectional area for allowing air flow from a first end (1411) to a second (1412), and an air drive disposed within the housing to draw air from the intake end and drive said air through the output end, the air drive comprising at least a first fan (1420a) of a first fan diameter and a second fan (1420b) of a second diameter, the first fan (1420a) and second fan (1420b) arranged to overlap within said housing (1004) such that a substantial portion of said duct cross-sectional area is covered. The cooling device (1003) may further comprise an inner duct (1424) for separating air flow between the first fan (1420a) and the second fan (1420b) through at least a portion of the housing (1004), and the first fan (1420a) and second fan (1420b) may be offset along the length of the duct.

### CROSS-REFERENCE TO RELATED APPLICATIONS

The present application claims priority to U.S. Provisional Application No. 60/941,597 filed on Jun. 1, 2007.

### FIELD OF THE DISCLOSURE

The present invention relates to a cooling device for electrical and electronic components and, in particular, a cooling device for installation in a computer.

### BACKGROUND

Heat generating electrical or electronic components include for example memory chips, CPUs, voltage regulators, drivers, etc. and generate heat that is deleterious to their operation and the operation of other system components.

Various cooling devices for cooling a heat generating electrical or electronic devices are known for computers. General information concerning cooling devices for electrical and electronic components may be reviewed by reference to International published application WO 03/007372, dated Jan. 23, 2003 to CoolIT Systems Inc., is incorporated herein by reference.

### SUMMARY

In accordance with a broad aspect of the present invention, there is provided a computer cooling device comprising a housing; a plurality of mounting devices on the housing, an air drive arrangement providing an active face of at least than 60 mm by 95 mm.

In accordance with another broad aspect of the present invention, there is provided a cooling system for a heat-generating component, the cooling system comprising: a housing; a plurality of mounting devices on the housing, a radiator in the housing for accommodating a circuit therethrough of liquid coolant; a pump in the housing for conducting liquid coolant through the radiator; and an air drive arrangement in the housing for driving a flow of air through the housing along at least a substantially linear path and through the radiator.

It is to be understood that other aspects of the present invention will become readily apparent to those skilled in the art from the following detailed description, wherein various embodiments of the invention are shown and described by way of illustration. As will be realized, the invention is capable for other and different embodiments and its several details are capable of modification in various other respects, all without departing from the spirit and scope of the present invention. Accordingly the drawings and detailed description are to be regarded as illustrative in nature and not as restrictive.

### BRIEF DESCRIPTION OF THE DRAWINGS

Referring to the drawings wherein like reference numerals indicate similar parts throughout the several views, several aspects of the present invention are illustrated by way of example, and not by way of limitation, in detail in the figures, wherein:

FIG. 1 is a perspective view of a portion of a computer case with a computer cooling system aligned for installation therein;

FIG. 2 is a perspective view of another portion of a computer case; and

FIG. 3 is a top plan view of a computer cooling system.

### DESCRIPTION OF THE VARIOUS EMBODIMENTS

The detailed description set forth below in connection with the appended drawings is intended as a description of various embodiments of the present invention and is not intended to represent the only embodiments contemplated by the inventor. The detailed description includes specific details for the purpose of providing a comprehensive understanding of the present invention. However, it will be apparent to those skilled in the art that the present invention may be practiced without these specific details.

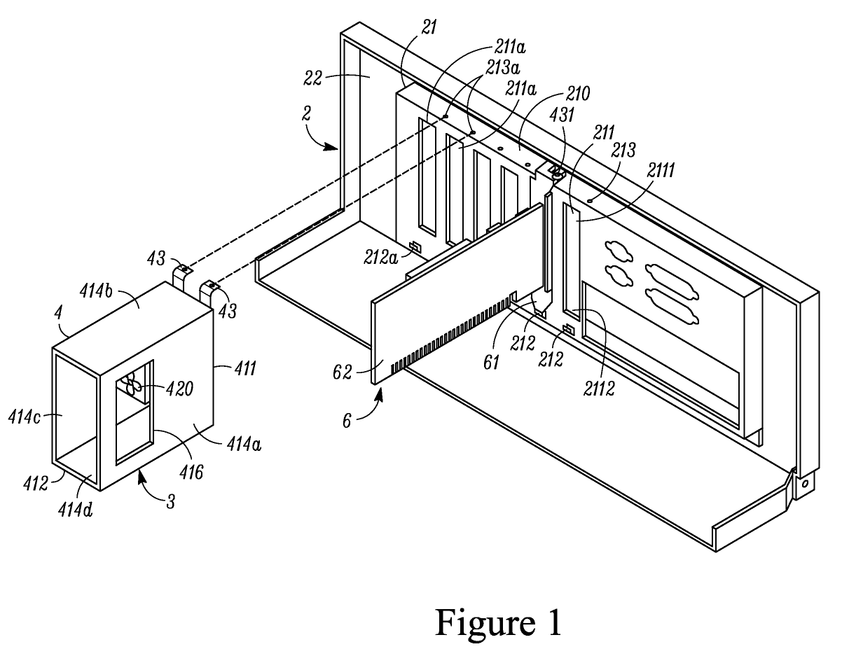

Referring to FIG. 1 an example embodiment of a portion of one type of computer casing is shown. The illustrated computer casing includes a case body 2. As illustrated, the component 6 is an expansion card, such as a VGA card, a game card, etc., and includes a backplate 61 secured to the case body 2 in a conventional manner, and a circuit board 62 connected to the backplate 61.

The computer casing 2 of this embodiment is configured for application to a desktop computer, and has a rear side wall 21 that is punched to form a series of expansion slots 211. The expansion slots 211 have opposite first and second ends 2111, 2112. Side wall 21 further includes a ledge 210 that is disposed adjacent to the first ends 2111 of the expansion slots 211, and a plurality of backplate retainers 212 that are adjacent to the second ends 2112 of the expansion slots 211 and that correspond respectively to the expansion slots 211. In this embodiment, each of the backplate retainers 212 is an angled retainer that cooperates with the side wall 21 to form a retaining space. The ledge 210 is formed with a plurality of fastener holes 213 that correspond respectively to the expansion slots 211. When mounting the component 6 on the side wall 21, the backplate 61 is brought into alignment with a selected expansion slot 211, and an upper end of the backplate 61 is fastened to the ledge 210 using a screw 431 that engages the fastener hole 213 corresponding to the selected expansion slot 211, whereas an opposite end of the backplate 61 is retained in the retaining space of the backplate retainer 212 corresponding to the selected expansion slot 211. Of course, other configurations are possible including other forms of backplates and expansion slot retaining devices including various combinations of fastener-based and interlocking-based, clips, clamps, brackets, etc. securing modes.

A cooling device 3 according to one aspect of the present invention is shown in a position for installation against at least one and in the illustrated embodiment two selected expansion slots 211a to use the expansion slots as a port through which heated air may be evacuated from the case. Cooling device 3 includes a housing 4 mountable on the side wall 21 inside the case body 2 such that the housing 4 is juxtaposed with one of the expansion slots 211. Cooling device 3 may include various parts for permitting the mounting thereof in alignment with the expansion slots. For example, device 3 may include angled tabs 43 on a first end 411 to be disposed on the ledge 210, and tabs (cannot be seen) to engage the backplate retainers 212a that correspond to the juxtaposed ones of the expansion slots 211a. Screw fasteners may engage the fastener holes 213a that correspond to the juxtaposed ones of the expansion slots 211 for fastening the tabs 43 to the ledge 210.

In this embodiment, the housing end 411 includes an opening for air passage therethrough and opposite end 412 also includes an opening, which in the illustrated embodiment spans the entire end to also allow air passage therethrough. Housing 4 further includes side walls, for example walls 414a-414d, extending between the ends 411, 412. Side walls define an open duct between ends through which air may pass from end to end. Any of side walls 414a-414d may include an opening, such as opening 416, if desired, to provide further air passages.

End to end air flow permits air to pass from or through the expansion slots and at the other end into or from the open area of the case. With such end to end flow, it is not necessary to rely on sideways air movement, through walls 414a-d, which may be blocked by cards in adjacent slots. In the illustrated embodiment, flow can pass through opening 416 but cooling operation is not reliant on such flow.

Housing 4 further accommodates one or more cooling mechanisms that act upon or drive the air flow as it passes from end to end. For example, in one embodiment, housing 4 accommodates an air drive arrangement configured to drive air flow through the walls 414a-d from end to end. In one embodiment, air drive arrangement includes at least one fan 420. In one embodiment, for example, fan 420 may be oriented to pull air from within case 2 through end 412 and drive the air out through end 411 and expansion slots 211a against which the device is installed.

Other cooling mechanisms may include for example, any or all of further fans, a liquid cooling device such as a radiator, etc.

Dimensions of cooling device 3 may be constrained by the size of the case, size of the slot areas, etc. It will be appreciated, for example, that standards may control the size of expansion slots. In addition, it may be desirable to limit the size of cooling device 3 so that it does not unnecessarily block adjacent expansion slots. For example, for a dual slot device, a reasonable maximum device thickness between outer surfaces of walls 414a and 414c is about 50 mm, and possibly 42 mm and a reasonable maximum device thickness between outer surfaces of walls 414b and 414d is about 130 mm, and possibly 120 mm.

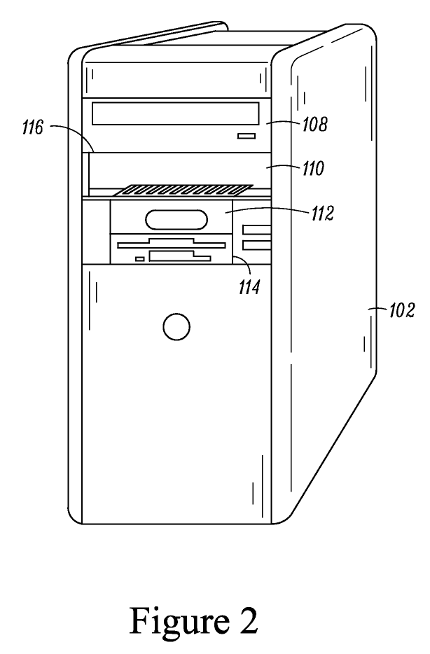

With reference to FIG. 2, another portion of a computer case 102 is shown. Computer case 102 includes peripheral/drive bays 108, 110, 112 & 114 in which peripheral devices or drives such as floppy disk drives, optical disc drives, tape backup drives, or the like may be received. For example, in the embodiment illustrated, computer case 102 includes two peripheral/drive bays 108 & 110 sized to receive 5¼ inch peripheral devices or drives. Drive bays 108 and/or 110 may be used to receive a computer cooling device, and the openings to the drive bays may be useful as openings through which heated air may be evacuated from the computer.

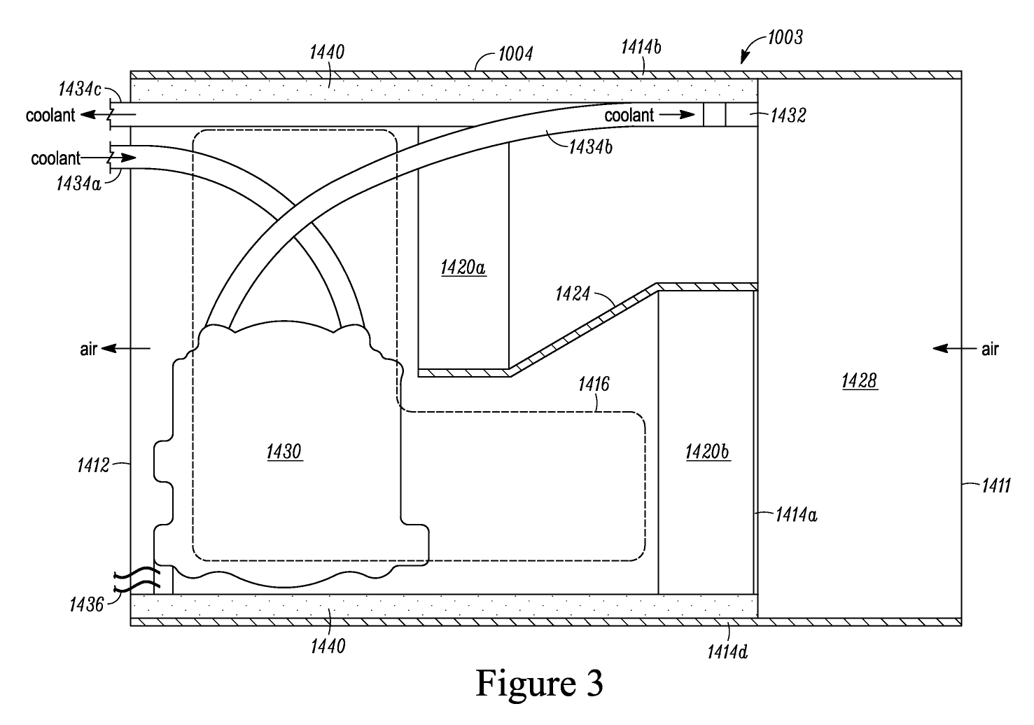

With reference to FIG. 3, for example, another embodiment of a cooling device 1003 is shown. Cooling device 1003 is mountable in a computer case in one or more drive bays. Cooling device 1003 is selected to be as large as possible while fitting into the drive bay area and without adversely crowding the other computer components. The size of the device dictates the volume of air that can be moved, so increasing the size allows a larger volume air flow and therefore greater cooling. A drive bay accepts a device width of about 150 mm. Thus, it is desired that the device allow for a flow of at least 70% of the available expansion slot width and may, for example, provide for an inner air passage width of at least about 95 mm. Reasonably, a device may be sized to fit into a dual 5¼ inch drive bay and have a maximum height of about 86 mm. In a computer cooler, it is desired that the device allow for a flow of at least 70% of the available bay height and may, for example, provide for an inner air passage width of at least about 60 mm. In the illustrated embodiment, device includes an outer dimension height of about 86 mm and an outer dimension width of about 145 mm and can be installed in a dual drive bay. Such dimensions will limit the size of the mechanisms of the device.

Cooling device 1003 includes a housing 1004 including a first end 1411, an opposite end 1412 and side walls, for example walls 1414a, 1414b, 1414d. Housing 1004 includes a further wall secured between walls 1414b and 1414d, but which has been removed in the Figure to facilitate illustration. The side walls are formed to secure in a drive bay including installation mechanisms, for example, grooves along walls 1414b and 1414d into which the ledge between adjacent drive bays may be inserted.

Ends 1411 and 1412 include openings therethrough such that air may pass through the housing from end to end. Ends may include grates or louvers to direct air flow or prevent access to the interior of housing 1004, while still allowing air flow therethrough. If desired, for additional air flow, one or more side wall openings may be provided, such as opening 1416 (shown in phantom in the wall removed between walls 1414b and 1414d.

Housing 1004 may accommodate one or more fans. The one or more fans may be selected to drive a maximum air flow as possible. As noted previously, the one or more fans may be selected to act on a cross sectional width of at least 95 mm and a cross section height of at least 60 mm. The one or more fans may be limited by the dimensions permitted for installation of a device at the expansion slots and may be for example no greater than 86×145 mm.

Housing 1004 accommodates a pair of fans, 1420a and 1420b, positioned to drive the movement of air from end 1411 to 1412. In the illustrated embodiment, fans are positioned to operate in a plane orthogonal to the axis of the housing between ends 1411 and 1412, which is also orthogonal to the desired substantially linear direction of the air flow through the housing. In the illustrated embodiment, fans 1420a, 1420b are selected to substantially fill the entire inner width of the housing from wall 1414b to wall 1414d and to fill substantially the entire inner height between wall 1414a and its opposite wall, not shown. In so doing, the two fans, 1420a and 1420b, are positioned in a side to side overlapping configuration and accommodating substantially the full height. For example, as shown, one fan 1420a has a 70 mm diameter and the second fan 1420b has an 80 mm diameter. Such fans not only substantially fill the inner cross sectional space of the housing 1004, but provide a maximized fan power for the available space. Although fan 1420a could be enlarged to about 80 mm to fully fill the inner height of the housing, it may be desirable to provide some space between the housing inner surface and the fan housing for the passage thereby of other structures, as will be described herein below.

To allow the fans to overlap in their active areas, the fans may be offset from a side by side position. For example, a first of the fans may be positioned a first distance from the end of the housing and the second fan may be positioned a distance from the end which is different than that of the first fan.

A duct 1424 may be positioned between the fans to control the source of air for the later acting fan. For example, it is desirable that the later acting fan, fan 1420b in the illustrated embodiment, draw its own source air, rather than simply drawing air already acted upon by the first fan 1420a. Duct 1424 creates a wall between the fans to limit the source of air acted upon by the later acting fan 1420b to air not already acted upon by fan 1420a.

In the illustrated embodiment, device 1003 further acts as a self contained liquid cooling accessory for a computer. In this embodiment, housing 1003 includes a liquid coolant radiator 1428 and a pump 1430. Radiator 1428 may take various forms and may for example, include a liquid coolant circuit therethrough between a first port 1432 and a second port (cannot be seen behind port 1432). Radiator 1428 may act to effect heat transfer from the liquid coolant to air passing thereby, as by use of heat transfer surfaces such as fins. Radiator 1428, to operate most efficiently may accommodate substantially the full internal cross sectional area of the housing. For example, in the illustrated embodiment the radiator is at least 60 mm×95 mm in face dimensions through which the air passes and may be about 86 mm×145 mm in face dimensions.

Pump 1430 is provided to drive liquid coolant through a circuit from a heat source (not shown) to radiator 1428. Pump 1430 may include an integral expansion vessel to simplify the overall device. Pump 1430 may be positioned to avoid blocking air flow from the fans. For example, although in the illustrated embodiment, the pump is positioned adjacent the outlet of fan 1420b, the pump is sized to permit space between the limits of the housing and the pump body. Pump 1430 may further be tilted to open up air flow spaces therepast.

Coolant lines 1434a, 1434b, 1434c may be provided to conduct coolant through the liquid cooled systems. Coolant line 1434c may extend to a heat source and line 1434a may return from a heat source, carrying thermal energy accepted therefrom.

An electrical supply may be required for operation of the device. In one embodiment, electrical lines 1436 extend for connection into the computer power supply. Of course, other types of electrical supplies may be provided, as desired, such as pinned contacts.

Housing 1004 may, if desired, be lined at least in part with an acoustical control material such as foam sheeting 1440.

It is to be understood that a device according to the present invention may include only a fan or a liquid cooling system to act as the device's cooling mechanism. However, a combination of devices may be used, if desired.

To connect a device such as that of FIG. 3 into a computer system for operation to cool its component parts, the housing may be inserted into the opening of two adjacent empty drive bays, such as bays 108, 110 with device 116 removed. The coolant lines 1434a, 1434c and any heat sink installed in circuit therewith may be mounted to accept thermal energy from a heat source. Electrical lines 1436 may be connected to a power supply. With this simple procedure a self contained liquid cooling solution may be installed for operation.

The system may operate to cool various components of the computer including CPU, memory chips, VGA card components, both through liquid cooling and through enhanced air flow. In particular, fans 1420a, 1420b may be driven to remove heated air out of the case and provide a flow of air past radiator 1428.

The previous description of the disclosed embodiments is provided to enable any person skilled in the art to make or use the present invention. Various modifications to those embodiments will be readily apparent to those skilled in the art, and the generic principles defined herein may be applied to other embodiments without departing from the spirit or scope of the invention. Thus, the present invention is not intended to be limited to the embodiments shown herein, but is to be accorded the full scope consistent with the claims, wherein reference to an element in the singular, such as by use of the article “a” or “an” is not intended to mean “one and only one” unless specifically so stated, but rather “one or more”. All structural and functional equivalents to the elements of the various embodiments described throughout the disclosure that are known or later come to be known to those of ordinary skill in the art are intended to be encompassed by the elements of the claims. Moreover, nothing disclosed herein is intended to be dedicated to the public regardless of whether such disclosure is explicitly recited in the claims. No claim element is to be construed under the provisions of 35 USC 112, sixth paragraph, unless the element is expressly recited using the phrase “means for” or “step for”.

1. A computer cooling device comprising:
a housing;
at least two expansion slot mounting devices on the housing; and
an air drive arrangement providing an active face of at least 60 mm by 95 mm.

2. The computer cooling device of claim 1, wherein said air drive provides air flow along a linear direction from a first end of said housing to an opposite end of said housing.

3. The computer cooling device of claim 1, wherein the air drive arrangement includes at least two fans.

4. The computer cooling device of claim 3, wherein said at least two fans each have a diameter of no greater than 86 mm.

5. The computer cooling device of claim 3, wherein said fans are positioned to overlap and substantially cover said active face.

6. The computer cooling device of claim 5, wherein said fans are linearly offset from each other within said housing.

7. A cooling device comprising:
a housing having an upper wall, a lower wall, and two sidewalls, said upper wall, lower wall and two sidewalls forming a duct, having a duct cross-sectional area, for allowing air flow from a first end, acting as an air intake end, to a second end acting as an air output end; and
an air drive disposed within said housing and arranged to draw air from said air intake end and drive said air through said housing to said output end, said air drive comprising at least a first fan of a first fan diameter and a second fan of a second diameter, said first fan and said second fan arranged to overlap within said housing such that a substantial portion of said duct cross-sectional area is covered.

8. The cooling device of claim 7, wherein said housing further comprises:
an inner duct for separating air flow between said first fan and said second fan through at least a portion of said housing.

9. The cooling device of claim 8, wherein said first fan and said second fan are offset along the length of said duct.

10. The cooling device of claim 7, further comprising:
a radiator disposed within said housing and receiving air flow from at least one of said first fan and said second fan, said radiator for containing a liquid coolant and having a first coolant line port and a second coolant line port;
a pump, coupled to said radiator by a first coolant line to said first coolant line port, and having a second coolant line coupled thereto for connecting to a coolant circuit external to said housing and for forming a coolant circuit via connection to said radiator second coolant line port, said pump for conducting said liquid coolant through said coolant circuit and through said radiator.

11. The cooling device of claim 7, wherein said duct cross-sectional area provides an air flow pathway of at least 60 mm by 95 mm.

12. The cooling device of claim 7, wherein said first fan diameter and said second fan diameter are each less than 86 mm.

13. The cooling device of claim 7, wherein said housing may be installed into a card expansion slot position of a card housing.

14. The cooling device of claim 13, further comprising;
at least one card expansion slot mounting bracket for installing said housing into at least one card expansion slot position.

15. The cooling device of claim 7, wherein said housing further comprises:
at least one air flow vent cutout in at least one of said upper wall, said lower wall, or one of said two sidewalls of said duct.

16. A cooling device comprising:
a housing;
at least two mounting devices on the housing;
a radiator in the housing for accommodating a circuit therethrough of liquid coolant;
a pump in the housing for conducting liquid coolant through the radiator; and
an air drive arrangement in the housing for driving a flow of air through the radiator.

17. The cooling device of claim 16, wherein said air drive arrangement comprises:
a first fan positioned within said housing;
a second fan position within said housing positioned linearly offset from said first fan and overlapping said first fan.

18. The cooling device of claim 17, wherein said air drive arrangement further comprises:
an inner duct within said housing for separating said first fan air flow from said second fan air flow.

19. The cooling device of claim 18, wherein said inner duct directs at least one of said first fan air flow or said second fan air flow through said radiator.

20. An electronic device card housing comprising said cooling device of claim 16.
